(19) United States
(12) Patent Application Publication
(10) Pub. No.: US 2009/0053487 A1
(43) Pub. Date: Feb. 26, 2009

(54) CERAMIC CIRCUIT BOARD AND MANUFACTURING METHOD THEREOF

(76) Inventors: Chih-Hung WEI, Taoyuan Hsien (TW); Yu Ping Hsieh, Taoyuan Hsien (TW)

Correspondence Address: BIRCH STEWART KOLASCH & BIRCH, PO BOX 747, FALLS CHURCH, VA, 22040-0747, US

(21) Appl. No.: 12/027,888

(22) Filed: Feb. 7, 2008

(30) Foreign Application Priority Data
Aug. 24, 2007 (TW) 096131430

(51) Int. Cl. G03F 7/00; B05D 5/12; B32B 3/00

(52) U.S. Cl. 428/210; 427/98.5; 430/313

(57) ABSTRACT

A ceramic circuit board and a manufacturing method thereof are disclosed. The method includes the steps of providing a first pre-mold plate and a first ceramic thin plate, stacking the first ceramic thin plate and the first pre-mold plate, and co-firing the first ceramic thin plate and the first pre-mold plate to commonly form the ceramic circuit board.

### CROSS REFERENCE TO RELATED APPLICATIONS

This Non-provisional application claims priority under 35 U.S.C. §119(a) on Patent Application No(s). 096131430 filed in Taiwan, Republic of China on Aug. 24, 2007, the entire contents of which are hereby incorporated by reference.

### BACKGROUND OF THE INVENTION

1. Field of Invention

The invention relates to a manufacturing method of a circuit board and, in particular, to a manufacturing method of a ceramic circuit board.

2. Related Art

Recently, the high element density has become a trend of developing electronic products while portable information electronic products and mobile communication products are developed toward the trends of miniaturization, multi-function, high reliability and low price. Thus, active devices and passive devices used in a circuit have been developed toward the trends of integration, system-on-chip and modularization so that the size of the circuit can be effectively reduced, the cost can be reduced, and the competition ability of the product can be enhanced.

The development of the low temperature sintered ceramics (LTCC) technology increases the volume availability of the electronic product by integrating the circuits of the electronic elements, including the passive devices and the active devices, in a multi-layer structure.

As shown in FIG. 1, a ceramic material and an inorganic adhesive are mixed to form slurry. Then, a scraper is provided to shape a pre-mold plate 11. Next, a conductive material is screen-printed on the pre-mold plate 11 to form a desired circuit pattern 111. Another pre-mold plate 12 is manufactured according to the same method, and a desired circuit pattern 121 is formed on the pre-mold plate 12 by way of screen printing. Finally, the two pre-mold plates 11 and 12 are stacked and pressed, and are then sintered at the temperature lower than 1000° C. so that a ceramic circuit board 2 is obtained. The two pre-mold plates 11 and 12 become two ceramic thin plates 21 and 22, respectively, and the conductive material forms two conductive layers 211 and 221.

The low-temperature co-firing ceramic technology can integrate circuits in a multi-layer structure to achieve the integration. Under the limitation of the diameter of the screen printing line, however, the line width of the circuit manufactured by the screen printing technology is restricted. Generally speaking, the line width of the circuit manufactured by the screen printing technology is about 100 times that of the circuit manufactured by the photolithography.

However, the current low-temperature co-firing ceramic technology cannot be combined with the photolithography to manufacture the fine circuit. The main reason is that the resist material and the developer adopted in the printed circuit board cannot be adapted to the pre-mold plate due to the organic formula of the pre-mold plate. Although some providers have provided the silver paste and the developer suitable for the exposure and the development of the pre-mold plate, the silver paste and the developer are only suitable for the pre-mold plate and have the high prices.

In addition, the pre-mold plates 11 and 12 may have different contraction amounts during the co-filing process, or the solvent or adhesive may volatilize to generate voids during co-firing. Thus, the ceramic thin plates 21 and 22 may have the problems of contraction, distortion and curved deformation, as shown in FIG. 1. This phenomenon becomes more obvious when the thinner ceramic thin plate is being manufactured. Due to the problem of deformation, the ceramic thin plate cannot be formed with the fine circuit using the suitable photolithography.

Thus, it is an important subject to provide a manufacturing method of a ceramic circuit board to manufacture a ceramic thin plate, in which the contraction can be effectively suppressed and no curved deformation is formed, and a fine circuit can be formed using the photolithography and the materials suitable for the exposure and the development of the printed circuit board so that the cost can be lowered and the integration degree of the ceramic circuit board can be enhanced.

### SUMMARY OF THE INVENTION

In view of the foregoing, the invention is to provide a manufacturing method of a ceramic circuit board, in which a fine circuit can be formed on the ceramic circuit board using a photolithography so that the cost can be lowered and the integration degree can be enhanced.

To achieve the above, the invention discloses a manufacturing method of a ceramic circuit board. The includes the steps of: providing a first pre-mold plate; co-firing the first pre-mold plate into a first ceramic thin plate; and forming a fine circuit pattern on the first ceramic thin plate by photolithography.

In addition, the manufacturing method of a ceramic circuit board of the invention includes the steps of: providing a first pre-mold plate and a first ceramic thin plate; stacking the first ceramic thin plate and the first pre-mold plate; and co-firing the first ceramic thin plate and the first pre-mold plate to commonly form the ceramic circuit board.

To achieve the above, the invention also discloses a ceramic circuit board, which is formed by adhering and co-firing at least one pre-mold plate and at least one ceramic thin plate. The ceramic thin plate has a patterned metal layer, a thin metal layer or a fine circuit pattern.

In addition, the invention further discloses a ceramic circuit board, which is formed by adhering and co-firing a plurality of ceramic thin plates. Each of the ceramic thin plates has a patterned metal layer, a thin metal layer or a fine circuit pattern.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic illustration showing a pre-mold plate sintered into a ceramic thin plate in the prior art;

FIG. 2 is a flow chart showing a manufacturing method of a ceramic circuit board according to an embodiment of the invention;

FIGS. 3 and 4 are schematic illustrations showing different aspects of a first pre-mold plate and a second pre-mold plate according to the invention; and

FIGS. 5A to 5E are schematic illustrations showing photolithography being performed on a ceramic thin plate according to the embodiment of the invention.

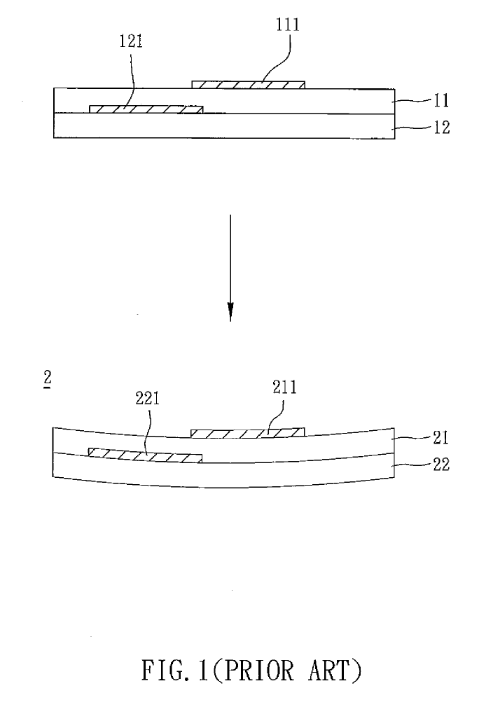

### DETAILED DESCRIPTION OF THE INVENTION

The present invention will be apparent from the following detailed description, which proceeds with reference to the accompanying drawings, wherein the same references relate to the same elements.

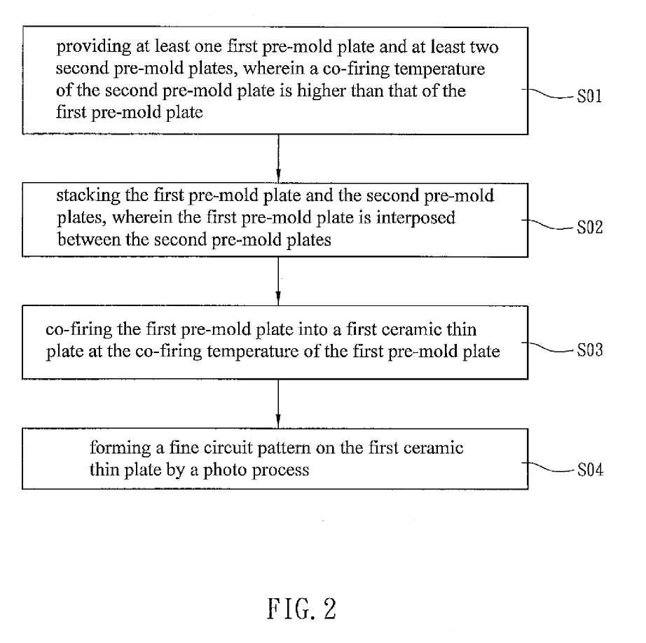

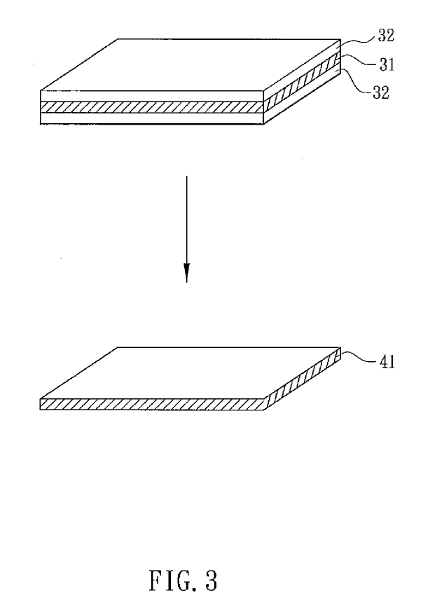

Referring to FIGS. 2 and 3, a manufacturing method of a ceramic circuit board according to an embodiment of the invention includes steps S01 to S04, which will be described in the following.

In the step S01, at least one first pre-mold plate 31 and at least two second pre-mold plates 32 are provided. A co-firing temperature of the second pre-mold plate 32 is higher than that of the first pre-mold plate 31. Each of the first pre-mold plate 31 and the second pre-mold plates 32 includes at least one ceramic material and an inorganic adhesive mixed together. The ceramic material is selected from the group consisting of a ceramic powder, a metal oxide powder, a composite metal oxide powder and combinations thereof. The inorganic adhesive can be made of glass.

The processes of preparing the first and second pre-mold plates 31, 32 will be described in the following. First, the ceramic material and the inorganic adhesive having the lower co-firing temperatures are mixed together to form the slurry, and the other ceramic material and the other inorganic adhesive having higher co-firing temperatures are mixed together to form the other slurry. The co-firing temperature can be lowered by the addition of the glass with the lower melting point, and the subsequent co-firing is prompted according to the liquid phase of the glass so as to achieve the co-firing fineness. In addition, a polymer adhesive, a plasticizer or an organic solvent can be added in order to prepare the slurry with the suitable viscosity. Thereafter, a scraper is utilized to shape the first pre-mold plate 31 and the second pre-mold plate 32.

In the step S02, the first and second pre-mold plates 31, 32 are stacked each other so that the first pre-mold plate 31 is interposed between the adjacent two second pre-mold plates 32. As shown in FIG. 3, the two second pre-mold plates 32 completely cover two opposite surfaces of the first pre-mold plate 31 to suppress the curved deformation of the first pre-mold plate 31 during the co-firing process. It is to be specified that the second pre-mold plates 32 do not have to be completely the same.

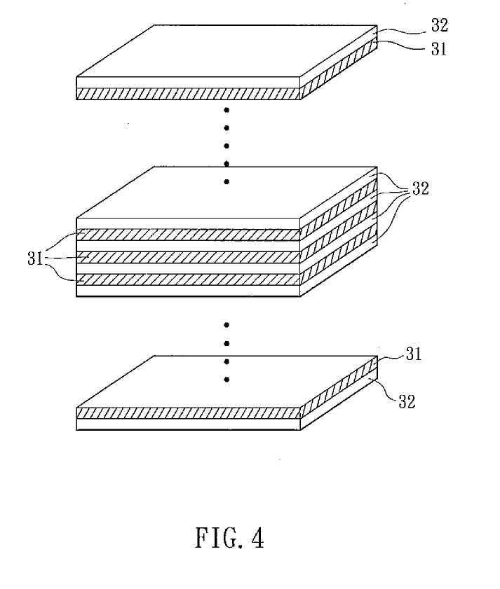

In addition, it is to be noted that the three pre-mold plates can be stacked together in this non-limitative embodiment. It is possible to stack the first and second pre-mold plates 31, 32 alternately according to the actual requirement so as to increase the number of stacked layers of the pre-mold plates (see FIG. 4) and to achieve the object of manufacturing ceramic thin plates with the same thickness or different thicknesses.

After the step S02, the manufacturing method can further include the step of pressing and stacking the first and second pre-mold plates 31, 32. That is, the hot pressing method and the isotatic pressing method are performed so that the pre-mold plates are stacked more densely and it is possible to prevent the pre-mold plates from being curved during the subsequent co-firing process.

In the step S03, the first pre-mold plate 31 is sintered into a first ceramic thin plate at the co-firing temperature of the first pre-mold plate 31. That is, the first pre-mold plate 31 with the lower co-firing temperature is sintered into the first ceramic thin plate, and the second pre-mold plates 32 with the higher co-firing temperature are not sintered. Herein, the second pre-mold plates 32 provide a stress action for suppressing the first pre-mold plate 31 from being curved, and the voids of the second pre-mold plates 32 that are not sintered may also serve as gas dissipating holes when the first pre-mold plate 31 is being sintered.

After the step S03, the manufacturing method can further include the step of removing the second pre-mold plates 32 so that a thin, smooth and fine first ceramic thin plate 41 is formed, as shown in FIG. 3. In this embodiment, the sintered first ceramic thin plate 41 is a low-temperature sintered ceramic (LTCC) thin plate. In addition, the manufacturing method can further include the step of testing the property of the first ceramic thin plate 41. For example, an instrument is utilized to test a dielectric constant (ε) and a quality factor (Q) of the first ceramic thin plate so that the first ceramic thin plate satisfying the specification requirement can be obtained.

As mentioned hereinabove, the first ceramic thin plate 41, which is free from the problems of contraction, distortion, and curved deformation and has the good fineness, the good dielectric property and the good quality property, can be obtained. Next, the step S04 can be performed to form a fine circuit pattern on the first ceramic thin plate 41 by a photolithography.

Before the photolithography is performed, a patterned metal layer may be formed on the first ceramic thin plate 41. The patterned metal layer can be formed on the sintered first ceramic thin plate 41 by way of screen printing on the first pre-mold plate 31, which has not been sintered. In addition, the patterned metal layer can be formed on the first ceramic thin plate by way of film deposition.

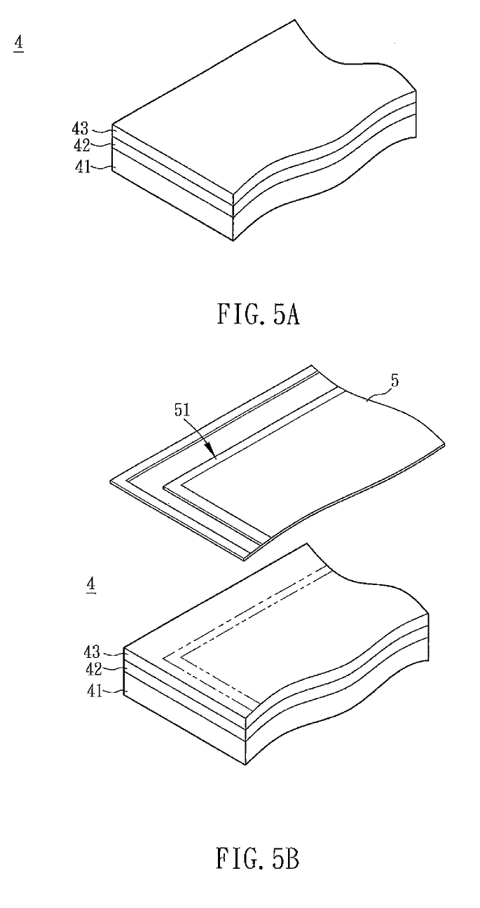

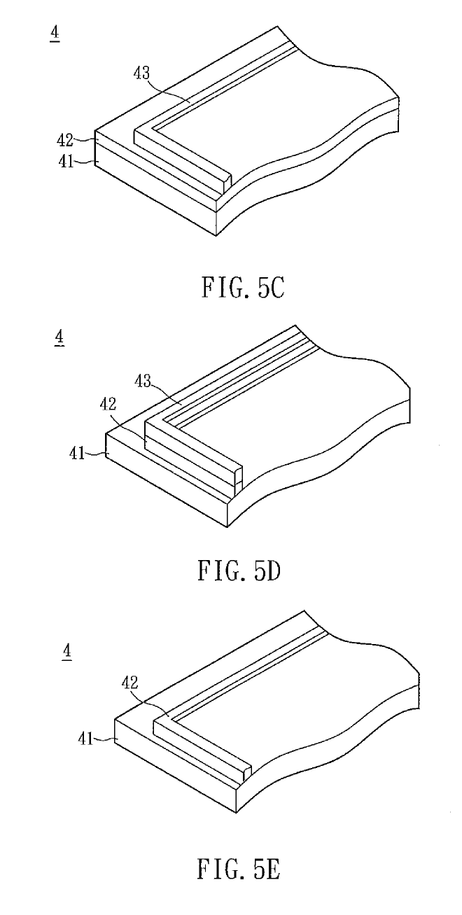

The method of manufacturing a ceramic circuit board 4 using the first ceramic thin plate 41 of this embodiment and the photolithography will be described with reference to FIGS. 5A to 5E, wherein a patterned metal layer 42 is disposed on the first ceramic thin plate 41. First, a photoresist layer 43 is applied onto the patterned metal layer 42, as shown in FIG. 5A. Next, a mask 5 having a shape corresponding to a fine circuit pattern 51 is disposed on the photoresist layer 43, as shown in FIG. 5B. Thereafter, the photoresist layer 43 is exposed through the mask 5 and then developed so that the exposed photoresist layer 43 can be removed and the fine circuit pattern 51 can be transferred on the photoresist layer 43, as shown in FIG. 5C. Next, the patterned metal layer 42 is etched so that the portion of the patterned metal layer 42, which is not protected by the photoresist layer 43, can be removed, as shown in FIG. 5D. Finally, a resist-removing liquid is provided to remove the residual photoresist layer 43 so that the fine circuit pattern 51 on the first ceramic thin plate 41 can be obtained, as shown in FIG. 5E.

Because the resist can be a positive resist or a negative resist, the exposure-development procedures in the photolithography are not limited to those mentioned hereinabove.

As mentioned hereinabove, the patterned metal layer 42 is changed to the fine circuit pattern 51 by the photolithography. According to the photolithography, the line width of the fine circuit pattern 51 of this embodiment may be smaller than 125 microns or even 35 microns. To be noted, the shape of the fine circuit pattern 51 in the drawing is for example only without limiting the scope of the invention, and can be designed according to the requirement.

In addition, the ceramic circuit board 4 of this embodiment may also be a ceramic circuit board with a multi-layer structure. In order to manufacture the ceramic circuit board with the multi-layer structure, the manufacturing method of this embodiment may further include the steps of: providing a second ceramic thin plate; stacking the first ceramic thin plate 41 and the second ceramic thin plate; co-firing the first ceramic thin plate 41 and the second ceramic thin plate to commonly form a ceramic circuit board. In order to make the first ceramic thin plate 41 and the second ceramic thin plate be connected together more densely, an adhesive may be interposed between the first ceramic thin plate 41 and the second ceramic thin plate. The adhesive may be an inorganic adhesive, such as glass, or a polymer adhesive, such as polyethylene glycol (PEG), polyvinyl butyal (PVB) or polyvinyl alcohol (PVA).

In this embodiment, the second ceramic thin plate can be manufactured according to the method of manufacturing the first ceramic thin plate 41, so detailed descriptions thereof will be omitted. In addition, a patterned metal layer may be formed on the second ceramic thin plate by way of screen printing, or another fine circuit pattern may be formed by the photolithography.

In addition to the formation of the ceramic circuit board with the multi-layer structure by combining the first ceramic thin plate 41 with the other ceramic thin plate, the ceramic circuit board with the multi-layer structure can be obtained by co-firing the first ceramic thin plate 41 and other pre-mold plates. Herein, the manufacturing method further includes the steps of: providing a third pre-mold plate; stacking the first ceramic thin plate 41 and the third pre-mold plate; and co-firing the first ceramic thin plate 41 and the third pre-mold plate to commonly form a ceramic circuit board.

The third pre-mold plate can be manufactured according to the method of manufacturing the first pro-mold plate 31 or the second pre-mold plate 32, so detailed descriptions thereof will be omitted. In addition, the third pre-mold plate may also be formed with a patterned metal layer by way of screen printing. In addition, the patterned metal layer may be changed to another fine circuit pattern by the photolithography after the co-firing process.

In summary, the manufacturing method of the ceramic circuit board of the invention is performed by interposing the first pre-mold plate with the lower co-firing temperature between the two second pre-mold plates each having the higher co-firing temperature, and co-firing the first pre-mold plate into the ceramic thin plate at the lower co-firing temperature, wherein the second pre-mold plate with the higher co-firing temperature is not sintered. The second pre-mold plates press the two opposite surfaces of the first pre-mold plate during the co-firing process to suppress the first pre-mold plate from being curved. Thus, the ceramic thin plate, which is free from the problems of contraction, distortion and curved deformation and has the good fineness, the good dielectric property and the good quality property, can be obtained.

In addition, the low-temperature co-firing ceramic (LTCC) technology of the invention is to sinter the ceramic thin plate and the pre-mold plate with different circuit designs or to sinter the ceramic thin plates with different circuit designs so that a 3D structure with integrated circuits is formed and the element can be minimized. Furthermore, the ceramic thin plate of the invention can be formed with the fine circuit by the photolithography and the materials of the exposure and the development adapted to the printed circuit board so that the cost can be saved and the integration degree of the ceramic circuit board can be enhanced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A manufacturing method of a ceramic circuit board, comprising steps of:
providing a first pre-mold plate;
sintering the first pre-mold plate into a first ceramic thin plate; and
forming a fine circuit pattern on the first ceramic thin plate.

2. The method according to claim 1, wherein a metal layer is formed on the first pre-mold plate before the first pre-mold plate is sintered into the first ceramic thin plate.

3. The method according to claim 2, wherein the metal layer is formed with the fine circuit pattern by photolithography.

4. The method according to claim 3, wherein the photolithography comprises steps of:
applying a photoresist layer onto the metal layer;
disposing a mask having a pattern corresponding to the fine circuit pattern on the photoresist layer;
exposing the photoresist layer through the mask and then developing the photoresist layer;
etching the metal layer; and
removing the photoresist layer to obtain the fine circuit pattern.

5. The method according to claim 1, wherein before the first pre-mold plate is sintered into the first ceramic thin plate, the method further comprises steps of:
providing at least two second pre-mold plates having a sintering temperature higher than that of the first pre-mold plate; and
interposing the first pre-mold plate between the adjacent two second pre-mold plates.

6. The method according to claim 1, further comprising a step of screen printing a patterned metal layer or a thin metal layer on the first pre-mold plate.

7. The method according to claim 1, further comprising steps of:
providing a second ceramic thin plate;
stacking the first ceramic thin plate and the second ceramic thin plate; and
co-firing the first ceramic thin plate and the second ceramic thin plate to form the ceramic circuit board.

8. The method according to claim 7, wherein an adhesive is disposed between the first ceramic thin plate and the second ceramic thin plate before the first ceramic thin plate and the second ceramic thin plate are sintered.

9. The method according to claim 7, further comprising steps of:
providing a third pre-mold plate disposed between the first ceramic thin plate and the second ceramic thin plate; and
co-firing the third pro-mold plate, the first ceramic thin plate and the second ceramic thin plate to form the ceramic circuit board.

10. The method according to claim 1, further comprising steps of:
providing a third pre-mold plate;
stacking the first ceramic thin plate and the third pre-mold plate; and
co-firing the first ceramic thin plate and the third pro-mold plate to commonly form the ceramic circuit board.

11. A manufacturing method of a ceramic circuit board, comprising steps of:
providing a first pre-mold plate and a first ceramic thin plate;
stacking the first ceramic thin plate and the first pre-mold plate; and
co-firing the first ceramic thin plate and the first pre-mold plate to commonly form the ceramic circuit board.

12. The method according to claim 11, wherein the first ceramic thin plate has a patterned metal layer or a thin metal layer.

13. The method according to claim 11, wherein an adhesive is disposed between the first pre-mold plate and the first ceramic thin plate before the first pre-mold plate and the first ceramic thin plate are sintered, wherein the adhesive is an inorganic adhesive, a polymer adhesive, glass, polyethylene glycol (PEG), polyvinyl butyal (PVB) or polyvinyl alcohol (PVA).

14. The method according to claim 11, further comprising steps of:
providing a second ceramic thin plate;
stacking the first pre-mold plate, the first ceramic thin plate and the second ceramic thin plate; and
co-firing the first pre-mold plate, the first ceramic thin plate and the second ceramic thin plate to form the ceramic circuit board.

15. A ceramic circuit board formed by co-firing at least one pre-mold plate and at least one ceramic thin plate having a patterned metal layer, a thin metal layer or a fine circuit pattern.

16. The ceramic circuit board according to claim 15, wherein the ceramic thin plate comprises a first ceramic thin plate and a second ceramic thin plate, and the pre-mold plate is stacked between the first ceramic thin plate and the second ceramic thin plate.

17. A ceramic circuit board formed by co-firing a plurality of ceramic thin plates, wherein each of the ceramic thin plates has a patterned metal layer, a thin metal layer or a fine circuit pattern.

18. The ceramic circuit board according to claim 17, wherein each of the ceramic thin plates is a low-temperature sintered ceramic (LTCC) thin plate.

19. The ceramic circuit board according to claim 17, wherein the ceramic thin plates are connected by an adhesive, inorganic adhesive or a polymer adhesive.

20. The ceramic circuit board according to claim 17, further comprising at least one pre-mold plate, wherein the pre-mold plate and the ceramic thin plates are adhered and sintered to form the ceramic circuit board.
